(19) United States
(12) Patent Application Publication
(10) Pub. No.: US 2011/0203665 A1
(43) Pub. Date: Aug. 25, 2011

(54) ADHESIVE SHEET AND SOLAR CELL INCLUDING THE SAME

(75) Inventor: Hisataka Kataoka, Yokohama-shi (JP)

(73) Assignee: BRIDGESTONE CORPORATION, Chuo-ku, Tokyo (JP)

(21) Appl. No.: 13/127,168

(22) PCT Filed: Oct. 26, 2009
(86) PCT No.: PCT/JP2009/068318

§ 371 Date: May 2, 2011

(30) Foreign Application Priority Data
Nov. 4, 2008 (JP) 2008-282727

(51) Int. Cl. H01L 31/0203; C08K 5/1515

(52) U.S. Cl. 136/259; 524/114

(57) ABSTRACT

An adhesive sheet having an improved durability is provided by preventing yellowing. The adhesive sheet of the invention is characterized by including ethylene-vinyl acetate copolymer, an organic peroxide, and an epoxidized fatty acid ester compound, the content of the epoxidized fatty acid ester compound being in the range of 0.1 to 14 parts by weight based on 100 parts by weight of ethylene-vinyl acetate copolymer.

### FIELD OF THE INVENTION

The present invention relates to an adhesive sheet including ethylene-vinyl acetate copolymer as a main component, having excellent resistance obtained by preventing yellowing.

### DESCRIPTION OF THE RELATED ART

In recent years, a solar cell, that is, a device directly converting solar energy into electric energy calls attention, from the viewpoints of effective use of natural resources and prevention of environmental pollution. The solar cells are being developed.

As shown in FIG. 1, a solar cell generally includes a front side transparent protection member 11, a front side sealing film 13A, photovoltaic cells 14 such as photovoltaic elements made of silicon, a back side sealing film 13B, and a back side protection member (back cover) 12, which are successively superimposed in this order. After the solar cell is subjected to vacuum degassing, heat and pressure are applied to the solar cell so that the front side sealing film 13A and back side sealing film 13B are made adhesively integral with each other by crosslinking or curing the films 13A and 13B. Known solar cells are prepared by connecting a plurality of photovoltaic cells 14 for generating a large electricity output. For maintaining the electric insulation property among the photovoltaic cells 14, the sealing films 13A and 13B having electric insulation property are used for sealing the photovoltaic cells.

Adhesive sheets including ethylene-vinyl acetate copolymer (EVA) are preferably used as front side and back side adhesive sheets, because EVA is low priced and has an excellent transparency. Moreover, the crosslinking density of the adhesive sheet is improved by adding a crosslinking agent such as organic peroxide to ethylene-vinyl acetate copolymer for improving the film strength and the durability.

In the solar cell, it is strongly desired that light incident on the solar cell is effectively taken into the photovoltaic elements of the solar cell as much as possible, for improving power generation efficiency. Hence, the adhesive sheet is desired to have high transparency, and therefore has properties for transmitting almost all the incident solar light without absorbing or reflecting the same.

When the solar cell is used for a long time period, however, ethylene vinyl acetate copolymer is deteriorated due to oxidation (oxidative deterioration). As a result, the adhesive sheet is sometimes discolored into yellow. The EVA oxidative deterioration is particularly accelerated under a high-temperature circumstance or ultraviolet irradiation. When the adhesive sheet is yellowed, not only the power generation property of the adhesive sheet, but also aesthetic property thereof is decreased.

It is considered that the EVA oxidative deterioration is caused by a crosslinking agent. Conventionally, the difference of yellowing is studied depending on the crosslinking agent, and then a specific crosslinking agent is used. For example, patent literature 1 discloses an adhesive sheet wherein alkyl-3,3-di (tert-butylperoxy)butyrate is used as a crosslinking agent. For restricting the EVA deterioration further efficiently, hindered phenol- or phosphite-based antioxidant is also used.
Patent Publication: JP-A 06-322334

### SUMMARY OF THE INVENTION

### Problem to be solved by the Invention

As a result of further studies by the inventors, it was found, in an adhesive sheet to which an antioxidant is added, that the antioxidant itself deteriorates over time by the irradiation of ultraviolet light. Consequently, it is possible that an adhesive sheet is yellowed. In the solar cells, a broad range of research and development is being carried out. For spreading the use of solar cells, it is necessary that the solar cells maintain an excellent power generating property and the aesthetic property of the film for a long period of time.

It is therefore an object of the present invention to provide an adhesive sheet having an improved durability by preventing the sheet from yellowing.

### Means for Solving the Problems

The above discussed problems of the present invention are solved by an adhesive sheet comprising ethylene-vinyl acetate copolymer; an organic peroxide; and an epoxidized fatty acid ester compound,

the content of epoxidized fatty acid ester compound being in the range of 0.1 to 14 parts by weight, based on 100 parts by weight of ethylene-vinyl acetate copolymer.

### Effect of the Invention

An epoxidized fatty acid ester compound is subjected to extremely small deterioration by ultraviolet light. Therefore, the adhesive sheet containing a predetermined amount of epoxidized fatty acid ester compound is highly restricted from the deterioration by yellowing, and has an excellent durability even under a high temperature circumstance or under ultraviolet irradiation. Moreover, solar cells are provided by using the adhesive sheet of the present invention, which maintain excellent power generating property and aesthetic property for a long time.

### BRIEF EXPLANATION OF THE DRAWINGS

FIG. 1 is a diagram for explaining a generally used solar cell.

FIG. 2 is a cross-section of a yellow index test module prepared in the example.

### EMBODIMENTS FOR CARRYING OUT THE INVENTION

An adhesive sheet of the present invention comprises, as basic components, ethylene-vinyl acetate copolymer, an organic peroxide, and an epoxidized fatty acid ester compound.

The epoxidized fatty acid ester compound is contained in the adhesive sheet in the range of 0.1 to 14 parts by weight, preferably in the range of 0.1 to 10 parts by weight, more preferably in the range of 0.3 to 10 parts by weight. An adhesive sheet, which contains the epoxidized fatty acid ester compound in the above content, has an excellent process ability, and hence an adhesive sheet having excellent durability can be obtained. Moreover, with the epoxidized fatty acid ester compound with the above content, it is possible to restrict bleeding out, that is, a phenomenon to have epoxidized fatty acid ester compound come out to the surface of the adhesive sheet. Consequently, the adhesive sheet can maintain excellent adhesive property for a long time.

The epoxidized fatty acid ester compound is prepared by epoxidizing an ester obtained by reacting fatty acid with an unsaturated bond with an aliphatic monovalent alcohol. As the epoxidized fatty acid ester compound, it is particularly preferable to use a material represented by formula (I):

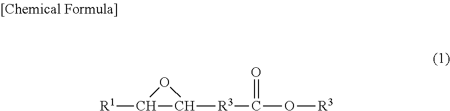

wherein R¹ and R³ represent a straight-chain or branched alkyl group, and R² represents a straight-chain or branched alkylene group.

R¹ and R³ in formula (I) are straight chain or branched alkyl groups. It is preferable that the alkyl group has 1 to 24, particularly 1 to 18 carbon atoms. Specific examples are straight chain alkyl groups such as methyl group, ethyl group, propyl group, butyl group, pentyl group, hexyl group, heptyl group, octyl group, nonyl group and decyl group, and branched alkyl groups such as isopropyl group, s-butyl group, t-butyl group, neopenthyl group, 1-ethylpropyl group and 2-ethylhexyl group.

Particularly preferable examples of R¹ are octyl group and dodecyl group. Particularly preferable examples of R³ are isobutyl group and 2-ethylhexyl group.

R² in formula (1) is straight-chain or branched alkylene group. It is preferable that the alkylene group has 1 to 24, particularly 1 to 18 carbon atoms. Specific examples are methylene group, ethylene group, n-propylene group, isopropylene group, n-butylene group, isobutylene group, sec-butylene group, tert-butylene group, n-pentylene group, iso-amylene group, tert-pentylene group, neopenthylene group, n-hexylene group, 4-methylpenthylene group, 1,3-dimethylbutylene group, 3,3-dimethylebutylene group, n-hepthylene group, 1-methylhexylene group, 3-methylhexylene group, 4-methylhexylene group, 5-methylhexylene group, 1-ethylpenthylene group, 1-(n-propyl)butylene group, 1,1-dimethylpenthylene group, 1,4-dimethylpenthylene group, 1,1-diethylpropylene group, 1,3,3-trimethylbutylene group, 1-ethyl-2,2-dimethypropylene group, n-octylene group, 2-ethylhexylene group, 1-methylhepthylene group, 2-methylhepthylene group, 5-methylhepthylene group, 1-propylpenthylene group, 2-propylpenthylene group, 1,1-dimethylhexylene group, 1,4-dimethylhexylene group, 1,5-dimethylhexylene group, 1-ethyl-1-methylpenthylene group, 1-ethyl-4-methylpenthylene group, 1,1,4-trimethylpenthylene group, 2,4,4-trimethylpenthylene group, 1-isopropyl-1,2-dimethylpropylene group, 1,1,3,3-tetramethylbutylene group, n-nonylene group, 1-methyloctylene group, 6-methyloctylene group, 1-ethylheptylene group, 1-(n-butyl)penthylene group, 4-methyl-1-(n-propyl)penthylene group, 1,5,5-trimethylhexylene group, 1,5,5-trimethylhexylene group, n-decylene group, 1-methylnonylene group, 1-ethyloctylene group, 1-(n-butyl)hexylene group, 1,1-dimethyloxytylene group, 3,7-dimethyloctylene group, n-undecylene group, 1-methyldecylene group, 1-ethylnonylene group, n-dodecylene group, 1-methylundecylene group, n-tridecylene group, n-tetradecylene group, 1-methyltridecylene group, n-pentadedecylene group, n-hexadecylene group, n-heptadecylene group, n-octadecylene group, n-nonadecylene group, and n-eicocylene group.

Particularly preferable examples of R² are 1-ethylpentylene group.

As specific examples of the epoxidized fatty acid ester compounds, isobutyl octyl oxirane-2-octanate, isobutyl 3-dodecyloxirane-2-octanate, and 2-ethylhexyl 3-octyloxirane-2-octanate are particularly preferably mentioned.

The adhesive sheet of the present invention comprises ethylene-vinyl acetate copolymer. In the ethylene-vinyl acetate copolymer, the content of vinyl acetate is in the range of 20 to 35 parts by weight, more preferably in the range of 22 to 30 parts by weight, and particularly preferably in the range of 24 to 28 parts by weight, based on 100 parts by weight of ethylene-vinyl acetate copolymer. The ethylene-vinyl acetate copolymer can be uniformly mixed with epoxidized fatty acid ester compound, whereby an adhesive sheet with excellent formability can be obtained.

The adhesive sheet of the present invention comprises an organic peroxide as a crosslinking agent. Therefore, EVA crosslinked, cured film is obtained for improving sealing property and durability of the solar cells.

Any types of organic peroxide can be used as long as the peroxide discomposes at a temperature at 100° C. or more, to generate a radical. Generally speaking, an organic peroxide to be used is selected, with the film forming temperature, conditions for formulating the composition, curing temperature, heat resistance of the adhesion substrate, and storage stability taking into account. In particular, it is preferable to use a material having a decomposition temperature of 70° C. or more in a 10-hour half-life time.

With a temperature for processing a resin, and a storage stability taking into account, examples of the organic peroxide are t-butylperoxy isopropyl carbonate, t-butylperoxy-2-ethylhexyl carbonate, 2,5-dimethylhexane-2,5-dihydroperoxide, 2,5-dimethyl-2,5-bis(t-butylperoxy)hexane, di-t-hexylperoxide, t-butylcumylperoxide, di-t-butylperoxide, 2,5-dimethyl-2,5-di(t-butylperoxy)hexane, dicumylperoxide, α,α′-bigt-butyloxyisopropylThenzene, n-butyl-4,4-bis(t-butylperoxy)valerate, 2,2-bis(t-butylperoxy)butane, 1,1-bis(t-butylperoxy)cyclohexane, 1,1-bis(t-hexylperoxy)-trimethylcyclohexane, 1,1-bis(t-butylperoxy)-3,3,5-trimethylcyclohexane, t-butylperoxybenzoate, benzoylperoxide, t-butylperoxy acetate, methyl ethyl ketone peroxide, 2,5-dimethyl-2,5-bis(t-butylperoxy)-3,3,5-trimethylcyclohexane, 1,1-bis(t-butylperoxy)cyclohexane, methyl ethyl ketone peroxide, 2,5-dimethyl-2,5-bisperoxy benzoate, t-butylhydroperoxide, p-menthane hydroperoxide, p-chlorobenzoyl peroxide, hydroxylheptyl peroxide, chlorohexanone peroxide, octanoyl peroxide, decanoyl peroxide, lauryl peroxide, cumyl peroxyoctoate, cuccinic acid peroxide, acetyl peroxide, t-butyl peroxy-2-ethylhexanoate, m-toluoyl peroxide, t-butylperoxy isobutyrate, and 2,4-dichlorobenzoyl peroxide. The organic peroxide can be used alone or in combination of two or more.

As the organic peroxide, it is preferable to use dialkyl peroxide as the organic peroxide. Such peroxide does not readily decompose even by the application of energy such as ultraviolet light or heat thereto. Therefore, the use will improve the durability of adhesive sheets for solar cells.

Examples of the dialkyl peroxides as the organic peroxide are α,α′-bis(tert-butyloxyisopropyl)benzene, dicumyl peroxide, di-t-hexylperoxide, 2,5-dimethyl-2,5-bis(t-butylperoxy)hexane, t-butylcumyl peroxide, and di-t-butylperoxide.

The content of the organic peroxide in the adhesive sheet is preferably in the range of 0.1 to 2.5 parts by weight, more preferably in the range of 0.5 to 2.0 parts by weight, based on 100 parts by weight of ethylene-vinyl acetate copolymer. When the content of the organic peroxide is within the above range, it is possible that the EVA is sufficiently crosslinked, and that the durability of the adhesive sheet is improved.

The adhesive sheet of the invention preferably contains a crosslinking auxiliary agent to enhance gel fraction of ethylene-vinyl acetate copolymer, and to improve sealing property and durability of the adhesive sheet. Examples of the crosslinking auxiliary agents (compound having a radical polymerizable group as a functional group) used for this purpose include tri-functional crosslinking auxiliary agents such as triallyl cyanurate and triallyl isocyanurate; and mono- and di-functional crosslinking auxiliary agents such as (meth)acrylic esters (e.g., NK esters). Among the materials, triallyl cyanurate and triallyl isocyanurate are preferable, and triallyl isocyanurate are particularly preferable.

The crosslinking auxiliary agent is in an amount or 5 parts by weight or less, more preferably in the range of 0.1 to 2.0 parts by weight, based on 100 parts by weight of EVA.

The adhesive sheet may further comprise a plasticizer, an adhesion improver, acryloxy-group containing compound and methacryloxy-group containing compound if necessary, for improving or adjusting various properties of the adhesive sheet (mechanical strength, adhesive property, optical properties such as transparency, heat resistance, light resistance, crosslinking rate), particularly for improving mechanical strength thereof.

Generally speaking, polybasic acid esters and polyhydric alcohol esters are used as the above mentioned plasticizer, although there is no special restriction to the plasticizer to be used. Examples of the plasticizer include dioctyl phthalate, dihexyladipate, triethylene glycol-di-2-ethylbutylate, butyl sebacate, tetraethylene glycol diheptanoate and triethylene glycol dipelargonate. The plasticizer can be used singly, or in combination of two or more kinds. The plasticizer is used preferably in an amount of not more than 5 parts by weight, based on 100 parts by weight of EVA.

As the adhesion promoter, a silane coupling agent can be used. By using the silane coupling agent, an adhesive sheet having an excellent adhesive property can be obtained. Examples of the silane coupling agent include γ-chloropropylmethoxysilane, vinylethoxysilane, vinyltris(β-methoxyethoxy)silane, γ-methacryloxypropyltrimethoxysilane, vinyltriacetoxysilane, γ-glycidoxypropyltrimethoxysilane, γ-glycidoxypropyl-triethoxysilane, β-(3,4-epoxycyclohexyl)ethyltrimethoxysilane, vinyltrichloroslane, γ-mercaptopropyltrimethoxysilane, γ-aminopropyltriethoxysilane, and N-β-(aminoethyl)-γ-aminopropyltrimethoxysilane. These silane coupling agents can be used alone or as a combination of two or more. The content of the adhesion promoter is preferably not more than 5 parts by weight, based on 100 parts by weight of EVA.

Generally speaking, acrylic acid or methacrylic acid derivatives, for instance, esters or amides of acrylic acid or methacrylic acid are used, as the above-mentioned acryloxy-group containing compound and the methacryloxy-group containing compound. Examples of the ester residue are straight-chain alkyl groups, such as methyl, ethyl, dodecyl, stearyl, lauryl, and cyclohexyl group, tetrahydrofurfuryl group, amino ethyl group, 2-hydroxyethyl group, 3-hydroxypropyl group, and 3-chloro-2-hydroxypropyl group. Examples of the amide are diacetone acrylamide. Further, it is possible to use esters obtained from a polyhydric alcohol such as ethylene glycol, triethylene glycol, polypropylene glycol, polyethylene glycol, triemthylol propane, or pentaerythritol and acrylic acid or methacrylic acid.

The acryloxy group-containing compound or methacryloxy group-containing compound is preferably contained in an amount of 0.5 to 5.0 parts by weight, and preferably 1.0 to 4.0 parts by weight, based on 100 parts by weight of EVA.

Further, the adhesive sheet of the present invention may further contain various additives such as a light stabilizer and anti-aging agent. By the adhesive sheet of the present invention including the light stabilizer, it is possible to prevent EVA from deterioration by the effect of light irradiation or the like, and the adhesive sheet from yellowing. A hindered amine light stabilizer can be used as the above-mentioned light stabilizer. Examples of the light stabilizer include LA-52, LA-57, LA-62, LA-63, LA-63p, LA-67 and LA-68 (each manufactured by ADEKA Co., Ltd.), Tinuvin 744, Tinuvin 770, Tinuvin 765, Tinuvin 144, Tinuvin 622LD, and CHIMASSORB 944LD (each manufactured by Ciba Specialty Chemicals Co., Ltd.), and UV-3034 (each manufactured by B.F. Goodrich). The light stabilizers can be used singly, or in combination of two or more kinds. The content of the light stabilizer to blend is preferably in the range of 0.01 to 5 parts by weight based on 100 parts by weight of EVA.

Examples of the anti-aging agent are hindered phenol antioxidants such as N,N′-hexane-1,6-diyl-bis[3-(3,5-di-tert-butyl-4-hydroxyphenyl) propionamide], phosphorus-type heat stabilizers, lactone-type heat stabilizers, vitamin E-type heat stabilizers and sulfur-type heat stabilizers.

The thickness of the adhesive sheet of the invention does not have any particular restriction, so far as the thickness is in the range of 50 μm to 2 mm.

It is possible that the adhesive sheet of the invention is prepared in accordance with a conventional method. For instance, the composition including the above-discussed materials such as EVA, organic peroxides, and epoxidized fatty acid ester is molded into a sheet-shaped article by extrusion molding, or calendar forming (calendaring). Alternatively, the composition is dissolved in a solvent, the thus obtained solution is applied to an appropriate substrate by an appropriate coater, and the applied solution is dried to obtain a coat. Thus, a sheet-shaped article can be prepared. When a film is formed by application of heat and pressure by extrusion molding or the like, the heat application is carried out generally in the range of 50 to 90° C.

The adhesive sheet of the present invention has an excellent durability with the deterioration due to yellowing being highly restricted for a long time, even under a severe circumstances such as high-temperature circumstance or ultraviolet irradiation circumstance. Moreover, the adhesive sheet has an excellent adhesive property with respect to a transparent substrate such as a plastic substrate or a glass substrate. It is possible to use the adhesive sheet as a sealing film for a solar cell, an intermediate film for a glass laminate or a adhesive film for an optical filter. The adhesive sheet of the present invention is particularly preferably used as a sealing film for a solar cell.

The structure of the solar cell obtained by use of the adhesive sheet of the present invention does not have any particular restriction. It is possible that the photovoltaic cell is sealed in the solar cell, by interposing the adhesive sheet(s) between the front side transparent protection member and the back side protection member, and that the adhesive sheet(s) is/are crosslinked so as to be integral with the photovoltaic cell and the protection members.

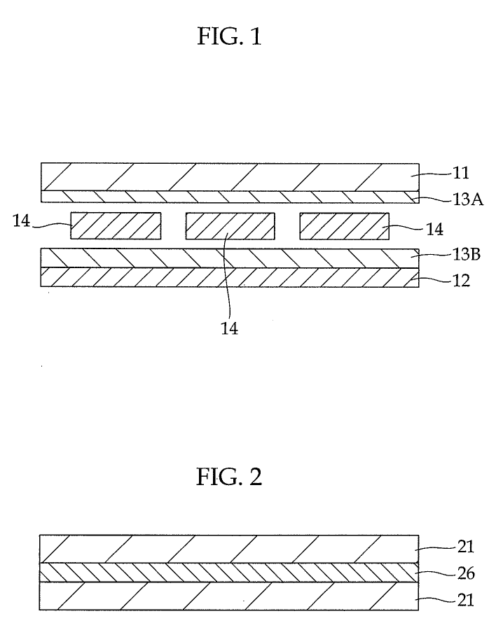

For sufficiently sealing the photovoltaic cell in the solar cell, the front side transparent protection member 11, front side sealing film 13A, photovoltaic cell(s) 14, back side sealing film 13B and back side protection member 12 are successively overlaid as shown in FIG. 1. Thereafter, the sealing film is crosslinked/cured in accordance with a conventional method such as heat and pressure application.

The thus obtained laminate is subjected to heat and pressure application at a temperature of 135 to 180° C., more preferably 140 to 180° C., in particular 155 to 180° C. by using a vacuum laminator with a degassing time of 0.1 to 5 minutes, a pressure of 0.1 to 1.5 kg/cm², and a pressure time of 5 to 15 minutes. When the heat and pressure application is carried out, EVA included in the front side sealing film and the back side sealing film is crosslinked. By the crosslinkage, the front side transparent protection member, back side protection member and photovoltaic cell(s) are integrated with each other via the front side sealing film and the back side sealing film. Thus, the photovoltaic cell(s) can be sealed.

In the present invention, a side of a photovoltaic cell from which the light is irradiated is referred to as “front side”, and a reversed side, with respect to the light receipt side, of photovoltaic cell is referred to as “bask side”.

The sealing film for a solar cell of the present invention can be preferably used as at least one of the front side and back side adhesive sheets. It is more preferable that the sealing film of the invention is used as both the front side and back side sealing films.

The front side transparent protection member for use in the solar cell of the invention is usually a glass substrate such as silicate glass. The thickness of the glass substrate is generally in the range of 0.1 to 10 mm, preferably in the range of 0.3 to 5 mm. Generally speaking, the glass plate can be thermally or chemically tempered.

The back side protection member for use in the present invention is a plastic film such as PET. In view of heat resistance, and heat and moisture resistance, a fluorinated polyethylene film, particularly a film obtained by laminating a fluorinated polyethylene film/Al/fluorinated poly ethylene film in this order is preferably used.

As mentioned previously, the solar cell of the present invention is characterized by the sealing films used on the front side and the back side. Namely, there is no particular restriction on the members except for the sealing films. In other words, the front side transparent protection member, back side protection member, and photovoltaic cell can have structures as those in the known solar cell.

### EXAMPLES

The present invention will now be explained by referring to Examples. The present invention is not restricted to the examples below.

### Example 1

An adhesive sheet (thickness: 1.0 mm) was prepared by calendar forming by using materials with the formulation below. The formulation was kneaded at 80° C. for 15 min. The temperature of the calendar rolls were 80° C., and the process rate was 5 m/min.

### Formulation:

EVA (vinyl acetate content: 26 parts by weight based on 100 parts by weight of EVA, “Ultracene 634” manufactured by Toso Company, Ltd.): 100 parts by weight

Crosslinking agent (2,5-dimethyl-2,5-bis(t-butylperoxy) hexane: 1.5 parts by weight

Epoxidized fatty acid ester compound (1) (epoxidized rapeseed fatty acid isobutyl ester, commercial name “Adekacizer D55” manufactured by ADEKA Co., Ltd.): 10.0 parts by weight

### Examples 2 to 7

Example 1 was repeated to prepare adhesive sheets of Examples 2 to 7, wherein the amount of epoxidized fatty acid ester compound (1) in Example 1 was changed into 5.0 parts by weight, 2.0 parts by weight, 1.4 parts by weight, 1.0 part by weight, 0.3 parts by weight, and 0.1 part by weight in Examples 2 to 7, respectively.

### Example 8

Example 1 was repeated to prepare an adhesive sheet of Example 8, wherein epoxidized fatty acid ester compound (1) in Example 1 was replaced by 2.0 parts by weight of epoxidized fatty acid ester compound (2) (epoxidized rapeseed fatty acid ester, commercial name “Adekacizer D178” manufactured by ADEKA Co., Ltd.) in Example 8.

Example 1 was repeated to prepare an adhesive sheet of Example 9, wherein epoxidized fatty acid ester compound (1) in Example 1 was replaced by 2.0 parts by weight of epoxidized fatty acid ester compound (3) (epoxidized rapeseed fatty acid ester, commercial name “Adekacizer D32” manufactured by ADEKA Co., Ltd.) in Example 9.

### Comparative Example 1

Example 1 was repeated to prepare an adhesive sheet of Comparative Example 1, wherein epoxidized fatty acid ester compound (1) was not used.

### Comparative Examples 2 to 4

Example 1 was repeated to prepare adhesive sheets of Comparative Examples 2 to 4, wherein the amount of epoxidized fatty acid ester compound (1) in Example 1 was changed into 15 parts by weight, 0.001 parts by weight, and 0.05 part by weight in Comparative Examples 2 to 4, respectively.

It was difficult to knead the formulation in Comparative Example 2, and an adhesive sheet could not be prepared therein.

### Comparative Examples 5 and 6

Example 1 was repeated to prepare adhesive sheets of Comparative Examples 5 and 6, wherein epoxidized fatty acid ester compound (1) in Example 1 was replaced by an antioxidant (1) (pentaerythritol=tetrakis (3-3′,5′-di-tert-butyl-4′-hydroxyphenyl propionate), commercial name “Adekastab A0-60” manufactured by ADEKA Co., Ltd.) in an amount of 0.5 parts by weight and 2.0 parts by weight, in Comparative Examples 5 and 6, respectively.

### Comparative Examples 7 and 8

Example 1 was repeated to prepare adhesive sheets of Comparative Examples 7 and 8, wherein epoxidized fatty acid ester compound (1) in Example 1 was replaced by an antioxidant (2) (dilauryl thiodipropyonate, commercial name “Adekastab A0-503” manufactured by ADEKA Co., Ltd.) in an amount of 0.5 parts by weight and 2.0 parts by weight, in Comparative Examples 7 and 8, respectively.

### Comparative Examples 9 and 10

Example 1 was repeated to prepare adhesive sheets of Comparative Examples 9 and 10, wherein the epoxidized fatty acid ester compound (1) in Example 1 was replaced by an antioxidant (3) (butylidene bis[2-tert-2-butyl-5-methyl-p-phenylene]-P,P,P′, P′-tetramidecyl bis(phosphine), commercial name “Adekastab 260” manufactured by ADEKA Co., Ltd.) in an amount of 0.5 parts by weight and 2.0 parts by weight, in Comparative Examples 9 and 10, respectively.

### [Evaluation]

The adhesive sheets prepared in the Examples and Comparative Examples were evaluated with respect to the yellow index after durability tests, in accordance with the following procedures:

### (1) Preparation of Test Modules

The adhesive sheets 26 prepared above were provided between two glass plates 21 (thickness: 3.0 mm) as shown in FIG. 2 and then sealed therein. Thus, modules for testing yellow index were prepared. The sealing was carried out by subjecting each laminate including a glass plate and an adhesive sheet to a heat and pressure application at 90° C. for 8 minutes in a vacuum laminator, followed by heating the same in an oven at 155° C. for 45 minutes.

(2) Measurement of Yellow Index after Heat Application

The test modules prepared above were left in an oven controlled to have a temperature at 120° C. for 2000 hours. The yellow index (YI) of the modules after being in the oven was measured by a spectrometer having multiple light source (in accordance with JIS K 7105, SM color computer, manufactured by Suga Test Instruments Co., Ltd. The results are shown in Tables 1 and 2.

(3) Measurement of Yellow Index after Irradiation of UV Light

To the text modules prepared above, ultraviolet light was irradiated at a radiant intensity of 1000 W/m² (Eye Super UV, manufactured by Iwasaki Electric Co., Ltd.) for 300 hours. The yellow index (YI) of the test modules after the irradiation was measured by using a spectrometer having multiple light source (in accordance with JIS K 7105, SM color computer, manufactured by Suga Test Instruments Co., Ltd. The results are shown in Tables 1 and 2.

TABLE 1

| | | Examples | | | | | | | | |
|---|---|---|---|---|---|---|---|---|---|---|
| | | 1 | 2 | 3 | 4 | 5 | 6 | 7 | 8 | 9 |
| Formulation | EVA | 100 | 100 | 100 | 100 | 100 | 100 | 100 | 100 | 100 |
| (parts by weight) | Crosslinking agent | 1.5 | 1.5 | 1.5 | 1.5 | 1.5 | 1.5 | 1.5 | 1.5 | 1.5 |
| | Epoxidized fatty acid ester | 10.0 | 5.0 | 2.0 | 1.4 | 1.0 | 0.3 | 0.1 | 0 | 0 |
| | compound (1) | | | | | | | | | |
| | Epoxidized fatty acid ester | 0 | 0 | 0 | 0 | 0 | 0 | 0 | 2.0 | 0 |
| | compound (2) | | | | | | | | | |
| | Epoxidized fatty acid ester | 0 | 0 | 0 | 0 | 0 | 0 | 0 | 0 | 2.0 |
| | compound (3) | | | | | | | | | |
| Evaluation | Yellow Index (YI) after heat | 3.1 | 3.4 | 4.2 | 2.9 | 6.3 | 6.0 | 6.9 | 4.5 | 4.6 |
| | application | | | | | | | | | |
| | Yellow Index (YI) after UV | 4.4 | 4.4 | 4.3 | 4.3 | 4.6 | 4.2 | 4.3 | 4.3 | 4.3 |
| | irradiation | | | | | | | | | |

TABLE 2

| | | Comparative Examples | | | | | | | | | |
|---|---|---|---|---|---|---|---|---|---|---|---|
| | | 1 | 2 | 3 | 4 | 5 | 6 | 7 | 8 | 9 | 10 |
| Formulation | EVA | 100 | 100 | 100 | 100 | 100 | 100 | 100 | 100 | 100 | 100 |
| (parts by weight) | Crosslinking agent | 1.5 | 1.5 | 1.5 | 1.5 | 1.5 | 1.5 | 1.5 | 1.5 | 1.5 | 1.5 |
| | Epoxidized fatty acid | 0 | 15.0 | 0.01 | 0.05 | 0 | 0 | 0 | 0 | 0 | 0 |
| | ester compound (1) | | | | | | | | | | |
| | Antioxidant (1) | 0 | 0 | 0 | 0 | 0.5 | 2.0 | 0 | 0 | 0 | 0 |
| | Antioxidant (2) | 0 | 0 | 0 | 0 | 0 | 0 | 0.5 | 2.0 | 0 | 0 |
| | Antioxidant (3) | 0 | 0 | 0 | 0 | 0 | 0 | 0 | 0 | 0.5 | 2.0 |
| Evaluation | Yellow Index (YI) | 9.5 | film | 9.4 | 9.4 | 15.0 | 9.0 | 7.7 | 5.5 | 14.1 | 8.8 |
| | after heat application | | formation | | | | | | | | |
| | | | impossible | | | | | | | | |
| | Yellow Index (YI) | 5.0 | film | 5.1 | 5.0 | 7.0 | 10.1 | 29.9 | 42.1 | 5.3 | 5.1 |
| | after UV irradiation | | formation | | | | | | | | |
| | | | impossible | | | | | | | | |

From Tables 1 and 2, it can be seen that the adhesive sheets prepared in the Examples have low yellow indexes both after heat application and UV irradiation, and that the durability is improved.

### EXPLANATION OF REFERENCE NUMERALS

11 Front side transparent protection member
12 Back side protection member
13A Front side sealing film
13B Back side sealing film
14 Photovoltaic cell
21 Glass plate
26 Sealing film

1. An adhesive sheet comprising:
ethylene-vinyl acetate copolymer;
an organic peroxide; and
an epoxidized fatty acid ester compound,
the content of epoxidized fatty acid ester compound being in the range of 0.1 to 14 parts by weight, based on 100 parts by weight of ethylene-vinyl acetate copolymer.

2. The adhesive sheet as claimed in claim 1, wherein the epoxidized fatty acid ester compound is represented by formula (I): 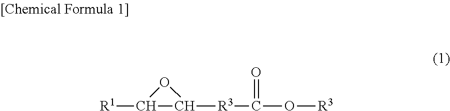
wherein R¹ and R³ represent a straight-chain or branched alkyl group, and R² represents a straight-chain or branched alkylene group.

3. The adhesive sheet as claimed in claim 1, wherein the content of the organic peroxide is in the range of 0.1 to 2.5 parts by weight, based on 100 parts by weight of ethylene-vinyl acetate copolymer.

4. A solar cell comprising:
a front side transparent protection member;
a back side protection member;
a sealing film interposed between the front side transparent protection member and the back side protection member;
a photovoltaic cell sealed by crosslinking the sealing film to make the photovoltaic cell integral with the sealing film, the sealing film being the adhesive sheet as claimed in claim 1.
